(19) United States
(12) Patent Application Publication
(10) Pub. No.: US 2024/0222908 A1
(43) Pub. Date: Jul. 4, 2024

(54) MOTION COMPONENT STRUCTURE

(71) Applicant: FIVEGRAND INTERNATIONAL CO., LTD., New Taipei City (TW)

(72) Inventor: TING-JUI WANG, New Taipei City (TW)

(21) Appl. No.: 18/366,625

(22) Filed: Aug. 7, 2023

(30) Foreign Application Priority Data
Jan. 4, 2023 (TW) 112100236

(51) Int. Cl. H01R 13/629

(52) U.S. Cl. CPC H01R 13/62988

(57) ABSTRACT

A motion component structure includes a motion part, an abutting part and an elastic element. The motion part includes a motion space; the abutting part is provided in the motion space; two ends of the elastic element respectively abut against the motion part and the abutting part, and the elastic element makes the motion part elastically move. Accordingly, the motion component structure can make the motion part provided at the object, and cooperate with the abutting part and the elastic element, so that the motion part and the abutting part are fastened to or unfastened from the object and the other object, so as to quickly combine and separate at least two objects, and achieve the effect of combining and separating repeatedly and quickly.

### CROSS-REFERENCE TO RELATED APPLICATION

This non-provisional application claims priority under 35 U.S.C. § 119(a) on Patent Application No(s). 112100236 filed in Taiwan, R.O.C. on Jan. 4, 2023, the entire contents of which are hereby incorporated by reference.

### BACKGROUND OF THE INVENTION

### 1. Field of the Invention

The present disclosure relates to a motion component structure, and in particular to a motion component structure that can be used to combine and separate at least two objects repeatedly and quickly.

### 2. Description of the Related Art

Generally, when combining at least one object, it is usually achieved by locking with screws to combine the object.

In terms of the above-mentioned customary fixing method, although at least one object can be fixed and combined in a manner that is not easy to separate, in addition to causing a situation that is not easy to assemble, at least one object will be difficult to disassemble because of the fixing and combining method of the screws.

### BRIEF SUMMARY OF THE INVENTION

In view of the above prior art, the inventor developed a motion component structure, with a view to achieving the effect of combining and separating repeatedly and quickly.

To achieve the above objective and other objectives, the present disclosure provides a motion component structure, including: a motion part, an abutting part and an elastic element. The motion part includes a motion space; the abutting part is provided in the motion space; two ends of the elastic element respectively abut against the motion part and the abutting part, and the elastic element makes the motion part elastically move.

In the above motion component structure, the motion part is provided with a fastening part, the fastening part is used to fasten an object.

In the above motion component structure, the abutting part is provided with a lifting and pulling part, the lifting and pulling part is used to lift and pull another object.

In the above motion component structure, the lifting and pulling part is used to assemble or movably assemble to the object, or the lifting and pulling part is assembled or movably assembled to the object by an assembling part.

In the above motion component structure, the abutting part or the assembling part is riveted, fastened, expanded, welded, locked or bolted to an object or a lifting and pulling part.

In the above motion component structure, the elastic element and the abutting part therebetween is provided with a corresponding member for corresponding and abutting.

In the above motion component structure, the motion part elastically abuts against the abutting part, so that a fastening part of the motion part is detached from an object, and actuates at a lifting and pulling part, or uses the lifting and pulling part to lift and pull another object.

In the above motion component structure, the motion part elastically abuts against the abutting part, so that a fastening part of the motion part is detached from an object.

In the above motion component structure, the motion part elastically abuts against the abutting part, so that a fastening part of the motion part is detached from an object, or a fastening part of the motion part abuts against an object.

In the above motion component structure, a corresponding member between the abutting part, a lifting and pulling part of the abutting part or the elastic element and the abutting part can move in the motion space.

In the above motion component structure, the motion part abuts against the abutting part by the elastic element, so that the motion space moves towards the abutting part.

In the above motion component structure, the abutting part is provided with a positioning part, the positioning part abuts against the elastic element at different angles to act as positioning.

In the above motion component structure, the abutting part has a corresponding member, wherein the corresponding member is combined to the abutting part, or the corresponding member and the abutting part are integrated into one.

In the above motion component structure, the motion part or the abutting part has a guide part, the guide part is used to guide the elastic element.

In the above motion component structure, the motion part is disposed at an object to pull up the object or another object, the object or the other object is a circuit board, chip, connector, heat dissipation body, hard disk, memory, IC, M2 memory, EI.S memory, E3.S memory, metal body or non-metal body.

In the above motion component structure, the other object is provided with a connector, the connector is used to connect with a corresponding connector of the object, or the connector is used to hot-plug with a corresponding connector of the object.

In the above motion component structure, the motion part is provided with a force-saving pushed part, the force-saving pushed part and the object are pushed to move the motion part.

In the above motion component structure, the abutting part is provided with a stopping part, the stopping part is used to stop or limit an object.

In the above motion component structure, the stopping part is provided with an orbital part, and the object moves along a direction of the orbital part.

In the above motion component structure, the abutting part is provided with at least one fixing part, and the object is fixed to the lifting and pulling part by the fixing part.

In the above motion component structure, the abutting part is provided with a lifting and pulling part, the lifting and pulling part is used to lift or assemble a circuit board, memory, IC, M2 memory, EI.S memory, E3.S memory, heat dissipation body, chassis, cabinet, metal body, or non-metal body.

In the above motion component structure, the abutting part is provided with a lifting and pulling part, or the lifting and pulling part is provided with at least one setting space.

In the above motion component structure, the object is provided with a corresponding connector, the corresponding connector passes through the setting space to butt a connector.

In the above motion component structure, the abutting part is provided at another object having the connector, the connector is pluggable with the corresponding connector of an object, or the connector is hot-pluggable with the corresponding connector of an object.

In the above motion component structure, the abutting part is provided with a lifting and pulling part, the lifting and pulling part assembles to another object having the connector, the connector is pluggable with the corresponding connector of an object, or the connector is hot-pluggable with the corresponding connector of an object.

Accordingly, the motion component structure according to the present disclosure can make the motion part provided at the object, and cooperate with the abutting part and the elastic element, so that the motion part and the abutting part are fastened to or unfastened from the object and the other object, so as to quickly combine and separate at least two objects, and achieve the purpose of combining and separating repeatedly and quickly.

### BRIEF DESCRIPTION OF THE DRAWINGS

FIG. 1 is a schematic view of a using state of a first embodiment of the present disclosure.

FIG. 2 is a schematic view of a second embodiment of the present disclosure.

FIG. 3 is a schematic view of a third embodiment of the present disclosure.

FIG. 4 is a schematic view 1 of a fourth embodiment of the present disclosure.

FIG. 5 is a schematic view 2 of the fourth embodiment of the present disclosure.

FIG. 6 is a schematic view of a fifth embodiment of the present disclosure.

FIG. 7 is a schematic view of a using state of the fifth embodiment of the present disclosure.

FIG. 8 is a schematic view of a using state of a sixth embodiment of the present disclosure.

FIG. 9 is a schematic view of a using state of a seventh embodiment of the present disclosure.

FIG. 10 is a schematic view 1 of a using state of an eighth embodiment of the present disclosure.

FIG. 11 is a schematic view 2 of the using state of the eighth embodiment of the present disclosure.

FIG. 12 is a schematic view of a using state of a ninth embodiment of the present disclosure.

FIG. 13A is a schematic outside view of a tenth embodiment of the present disclosure.

FIG. 13B is a schematic outside view of an eleventh embodiment of the present disclosure.

FIG. 14 is a sectional view 1 of a using state of the tenth embodiment of the present disclosure.

FIG. 15 is a schematic view 2 of the using state of the tenth embodiment of the present disclosure.

FIG. 16 is a schematic view of a using state of a twelfth embodiment of the present disclosure.

FIG. 17 is a schematic outside view of a thirteenth embodiment of the present disclosure.

FIG. 18 is a schematic view of a using state of a fourteenth embodiment of the present disclosure.

FIG. 19 is a schematic view of a using state of a fifteenth embodiment of the present disclosure.

### DETAILED DESCRIPTION OF THE INVENTION

To facilitate understanding of the purpose, characteristics and effects of the present disclosure, embodiments together with the attached drawings for the detailed description of the present disclosure are provided as below.

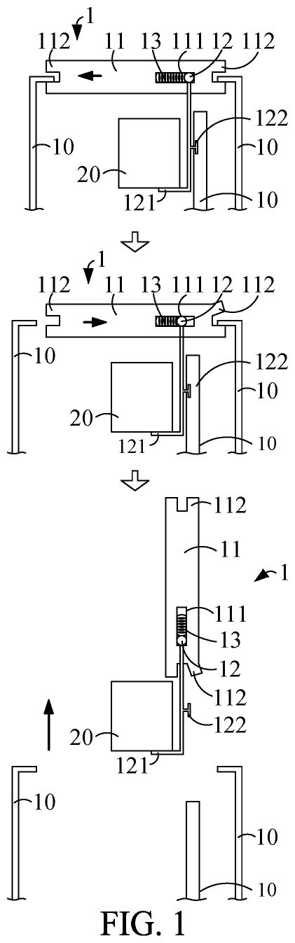

Referring to FIG. 1, as shown in the drawing, the present disclosure provides a motion component structure 1, which includes a motion part 11, an abutting part 12 and an elastic element 13.

The motion part 11 includes a motion space 111.

The abutting part 12 is provided in the motion space 111.

Two ends of the elastic element 13 respectively abut against the motion part 11 and the abutting part 12, and the elastic element 13 makes the motion part 11 elastically move.

When used, the motion component structure 1 may be provided at an object by the motion part 11 thereof, and may be combined to the object 10 and another object 20 by the abutting part 12, and the motion part 11 may be used to cooperate with the abutting part 12 and the elastic element 13 during actuation, so that the motion part 11 and the abutting part 12 are fastened to or unfastened from the object and the other object 20, so as to quickly combine and separate at least two objects, and achieve the effect of combining and separating repeatedly and quickly.

In addition to the above embodiment, in one embodiment of the present disclosure, the motion part 11 is provided with a fastening part 112, the fastening part 112 is used to fasten the object 10, in the present embodiment, two ends of the motion part 11 are respectively provided with a fastening part 112, the motion part 11 elastically abuts against the abutting part 12, so that the fastening part 112 at one end of the motion part 11 is detached from the object 10, and the fastening part 112 at the other end of the motion part 11 abuts against the object 10, so that the fastening parts 112 of the motion part 11 is detached from the object 10; and the abutting part 12 is provided with a lifting and pulling part 121, the lifting and pulling part 121 is used to lift and pull the other object 20, the lifting and pulling part 121 is used to assemble or movably assemble to the object 10, or the lifting and pulling part 121 is assembled or movably assembled to the object 10 by an assembling part 122.

Based on the above embodiments, when used, the fastening parts 112 of the motion part 11 may be fastened to the object 10, and the abutting part 12 is used to directly combine or the assembling part 122 is used to combine to the object 10 and the other object 20; and the motion part 11 is moved during actuation, so that the motion part 11 abuts against the abutting part 12 by the elastic element 13 to make the motion space 111 move towards the abutting part 12, the fastening part 112 at one end of the motion part 11 is detached from the object 10, so that the motion part 11 uses the elastic element 13 to elastically abut against the abutting part 12, the fastening part 112 at the other end of the motion part 11 abuts against the object 10, so that the fastening parts 112 of the motion part 11 are detached from the object 10, the motion part 11 then drives the lifting and pulling part 121, so that the lifting and pulling part 121 moves on the object 10 by the assembling part 122, and then the lifting and pulling part 121 is used to lift and pull the other object 20. Thus, the motion part 11 can cooperate with the abutting part 12 and the elastic element 13, so that the motion part 11 and the abutting part 12 are fastened to or unfastened from the object 10 and the other object 20, so as to quickly combine and separate at least two objects, and achieve the effect of combining and separating repeatedly and quickly.

In addition to the above embodiments, in one embodiment of the present disclosure, the abutting part 12 may be riveted, fastened, expanded, welded, locked or bolted to the object 10 or the lifting and pulling part 121; and the assembling part 122 may be riveted, fastened, expanded, welded, locked or bolted to the object 10 or the lifting and pulling part 121. Thus, the abutting part 12 of the present disclosure may further meet the needs of practical application.

In addition to the above embodiments, in one embodiment of the present disclosure, the abutting part 12 is provided with a lifting and pulling part 121, the lifting and pulling part 121 may at least be used to lift (or assemble) a circuit board, memory, IC, M2 memory, EI.S memory, E3.S memory, heat dissipation body, chassis, cabinet, metal body, or non-metal body. Thus, the lifting and pulling part 121 of the present disclosure may further meet the needs of practical application.

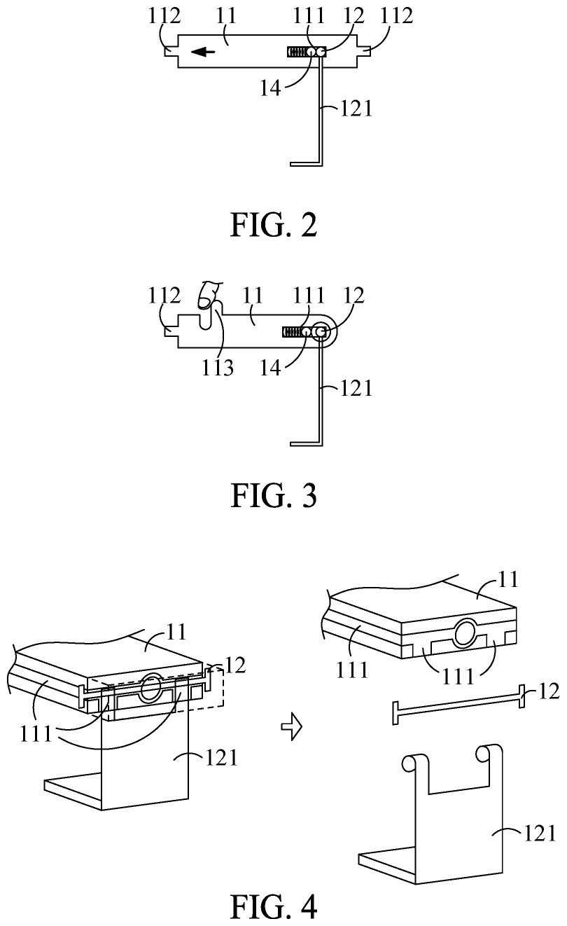

Referring to FIG. 2, as shown in the drawing, in addition to the above embodiments, in one embodiment of the present disclosure, the elastic element 13 and the abutting part 12 of the motion component structure 1 therebetween is provided with a corresponding member 14 for corresponding and abutting; when the motion part 11 is moved to actuate, the abutting part 12, the lifting and pulling part 121 of the abutting part 12, the elastic element 13 and the corresponding member 14 move in the motion space 111. Thus, the motion part 11 may cooperate with the abutting part 12, the elastic element 13 and the corresponding member 14, so that the motion part 11 and the abutting part 12 are fastened to or unfastened from the object and the other object 20 described in the above embodiment, so as to quickly combine and separate at least two objects, and achieve the effect of combining and separating repeatedly and quickly.

Referring to FIG. 3, as shown in the drawing, in addition to the above embodiments, in one embodiment of the present disclosure, the motion part 11 is provided with an operating part 113, and when the motion part 11 is operated, force may be applied to the operating part 113, whereby the operating part 113 is used to make the motion part 11 easy to operate.

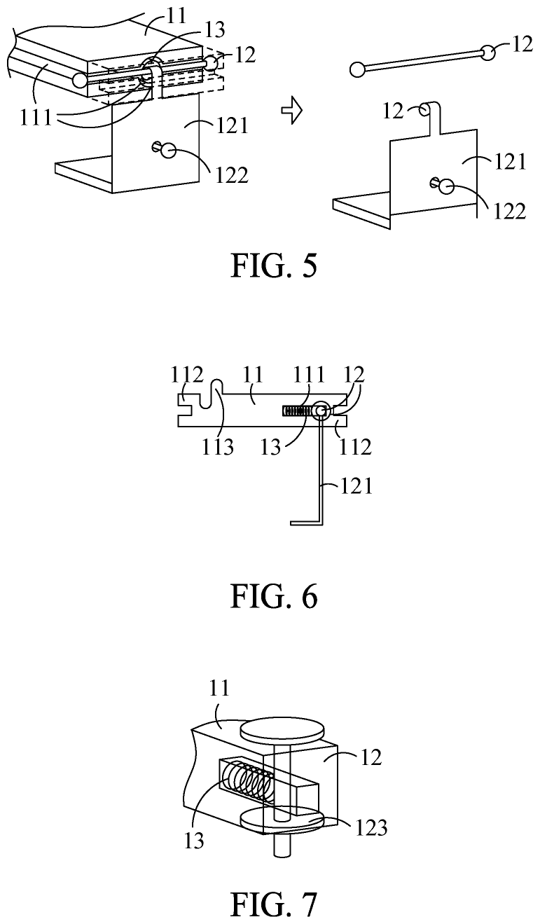

Referring to FIG. 4 to FIG. 6, as shown in the drawings, in addition to the above embodiments, in one embodiment of the present disclosure, the abutting part 12 may be a bolt body to make the abutting part 12 and the lifting and pulling part 121 combined in a bolted manner, so that the lifting and pulling part 121 is movably combined at the abutting part 12, and the motion part 11 abuts against the abutting part 12 by the elastic element 13, so that the motion space 111 moves towards the abutting part 12. Thus, after the fastening parts 112 of the motion part 11 is detached from the object 10, the motion part 11 may be rotated by the abutting part 12 (bolt body) so that the motion part 11 drives the lifting and pulling part 121 at an appropriate angle, and then the other object 20 is lifted by the lifting and pulling part 121, so that the motion part 11 and the abutting part 12 are fastened to or unfastened from the object 10 and the other object 20 described in the above embodiment, so as to quickly combine and separate at least two objects, and achieve the effect of combining and separating repeatedly and quickly.

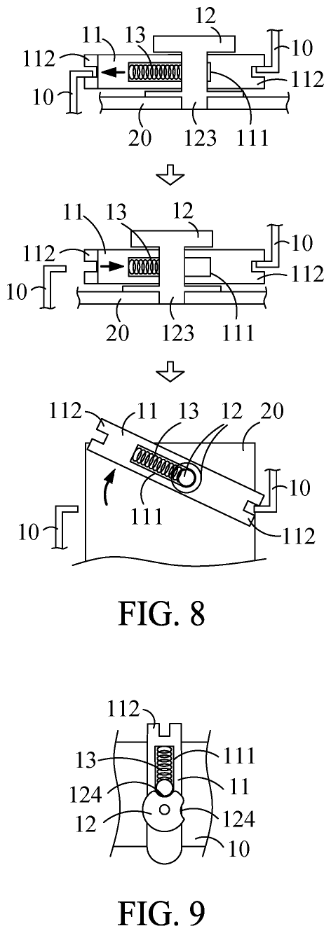

Referring to FIGS. 7 and 8, as shown in the drawings, in addition to the above embodiments, in one embodiment of the present disclosure, the abutting part 12 is provided with a combining part 123, and the abutting part 12 is movably assembled to the object 10 by the combining part 123; thus, after the fastening parts 112 of the motion part 11 is detached from the object 10, the abutting part 12 moves on the object 10 by the combining part 123, thereby moving the other object 20; accordingly, the motion part 11 and the abutting part 12 are fastened to or unfastened from the object 10 and the other object 20 described in the above embodiment, so as to quickly combine and separate at least two objects, and achieve the effect of combining and separating repeatedly and quickly.

Referring to FIG. 9, as shown in the drawing, in addition to the above embodiments, in one embodiment of the present disclosure, the abutting part 12 is provided with a positioning part 124, the positioning part 124 abuts against the elastic element 13 at different angles to act as positioning. Thus, the motion part 11 may be cooperated with the positioning part 124 to make the motion part 11 positioned at an appropriate angle after rotation, so that the abutting part 12 of the present disclosure can further meet the needs of practical application.

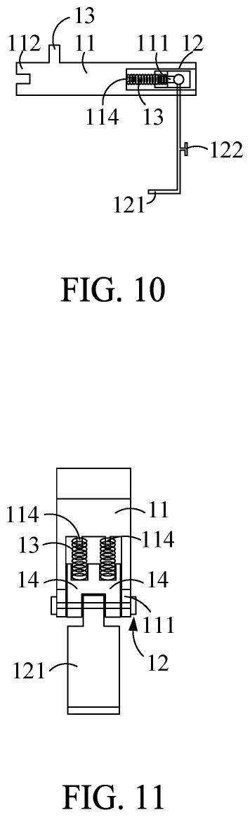

Referring to FIG. 10 and FIG. 11, as shown in the drawings, in addition to the above embodiments, in one embodiment of the present disclosure, the corresponding member 14 is combined to the abutting part 12 (or the corresponding member 14 and the abutting part 12 are integrated into one), and the motion part 11 (or the abutting part 12) has a guide part 114, the guide part 14 is used to guide the elastic element 13.

When the motion part 11 is moved to actuate, the abutting part 12, the lifting and pulling part 121 of the abutting part 12, the elastic element 13 and the corresponding member 14 move in the motion space 111, and the guide part 14 guides the elastic element 13 for elastic compression or elastic release. Thus, the motion part 11 may cooperate with the abutting part 12, the elastic element 13 and the corresponding member 14, so that the motion part 11 and the abutting part 12 are fastened to or unfastened from the object 10 and the other object 20 described in the above embodiment, so as to quickly combine and separate at least two objects, and achieve the effect of combining and separating repeatedly and quickly.

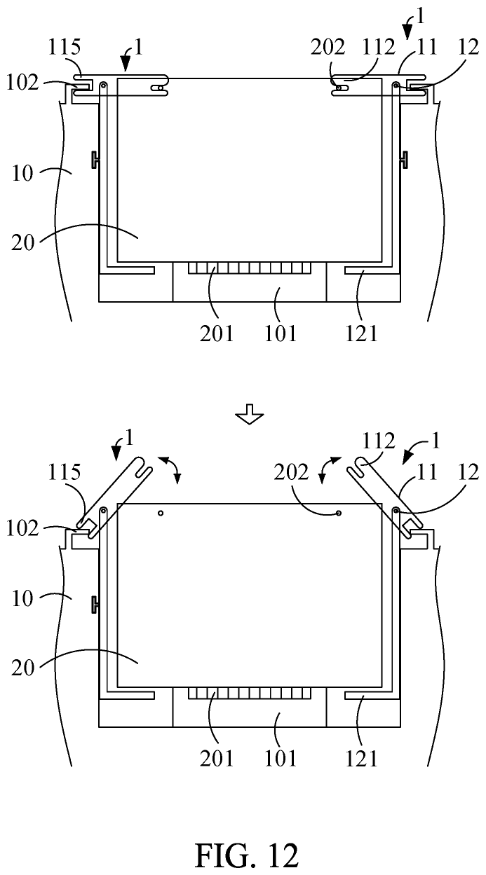

Referring to FIG. 12, as shown in the drawing, in addition to the above embodiments, in one embodiment of the present disclosure, the motion part 11 is disposed at an object 10 to pull up another object 20 (or the object 10), the object 10 or the other object 20 may be a circuit board, chip, connector, heat dissipation body, hard disk, memory, IC, M2 memory, EI.S memory, E3.S memory, metal body or non-metal body.

In addition to the above embodiments, in one embodiment of the present disclosure, the other object 20 is provided with a connector 201, the connector 201 is used to connect with a corresponding connector 101 of the object 10, or the connector 201 is used to hot-plug with a corresponding connector 101 of the object 10.

In addition to the above embodiments, in one embodiment of the present disclosure, the motion part 11 is provided with a force-saving pushed part 115, the force-saving pushed part 115 and the object 10 may be force-savingly pushed or pushed by a lever to move the motion part 11, and the force-saving pushed part 115 may be equivalent to the fastening part 112 in the above embodiment; in the present embodiment, one end of the motion part 11 is provided with the fastening part 112, and the other end of the motion part 11 is provided with the force-saving pushed part 115.

Based on the above embodiments, when used, one, two or more motion component structures 1 may be provided (two motion component structures 1 are provided in the present embodiment), the fastening part 112 is used to fasten the positioning part 202 of the other object 20, the force-saving pushed part 115 is used to fasten the corresponding part 102 of the object 10, after the fastening part 112 of the motion part 11 is detached from the positioning part 202 of the other object 20, the force-saving pushed part 115 and the corresponding part 102 of the object 10 are pushed to move the motion part 11, so that the motion part 11 drives the lifting and pulling part 121 of the abutting part 12 at an appropriate angle, and then the other object 20 is moved upwards by the lifting and pulling part 121, and the connector 201 separates from the corresponding connector 101 at the same time; accordingly, the motion part 11 and the abutting part 12 are fastened to or unfastened from the object 10 and the other object 20, so as to quickly combine and separate at least two objects, and achieve the effect of combining and separating repeatedly and quickly.

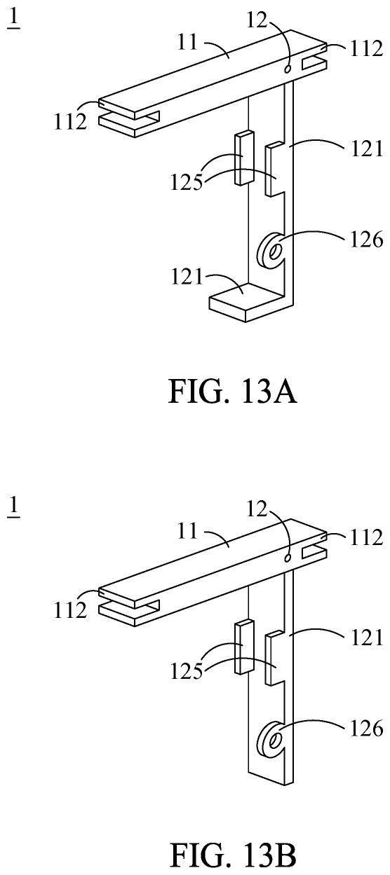

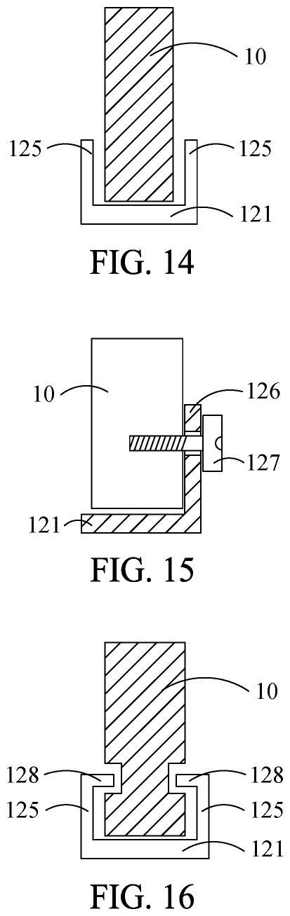

Referring to FIG. 13A to FIG. 16, as shown in the drawings, in addition to the above embodiments, in one embodiment of the present disclosure, the motion component structure 1 may be provided with a stopping part 125, the lifting and pulling part 121 is provided with at least one stopping part 125 in the present embodiment (the present disclosure takes two as an example), the stopping part 125 is used to stop or limit the object 10 (as shown in FIG. 14). Thus, the lifting and pulling part 121 of the present disclosure may cooperate with the stopping part 125 to further meet the needs of practical application.

In addition to the above embodiments, in one embodiment of the present disclosure, the lifting and pulling part 121 is provided with at least one fixing part 126, and the object 10 is fixed to the lifting and pulling part 121 by the fixing part 126 cooperating with a fixing element 127 (as shown in FIG. 15). Thus, the lifting and pulling part 121 of the present disclosure may cooperate with the fixing part 126 and the fixing element 127 to further meet the needs of practical application.

In addition to the above embodiments, in one embodiment of the present disclosure, the stopping part 125 is provided with an orbital part 128, which can make the stopping part 125 as a limit to the object 10, and allow the object 10 to move along a direction of the orbital part 128 (as shown in FIG. 16). Thus, the lifting and pulling part 121 of the present disclosure may cooperate with the stopping part 125 and the orbital part 128 to further meet the needs of practical application.

Further, the motion component structure 1 may be provided with the lifting and pulling part 121 (as shown in FIG. 13A) according to the needs of practical application, or not provided with the lifting and pulling part 121 (as shown in FIG. 13B). Thus, the motion component structure 1 of the present disclosure may further meet the needs of practical application.

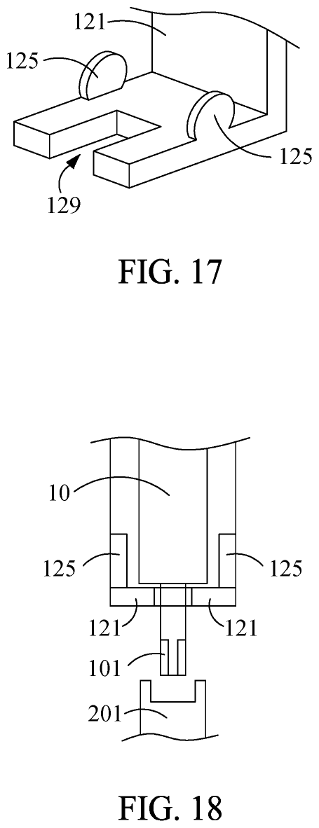

Referring to FIG. 17 and FIG. 18, as shown in the drawings, in addition to the above embodiments, in one embodiment of the present disclosure, the lifting and pulling part 121 of the motion component structure 1 may be provided with at least one setting space 129, and the object 10 is provided with a corresponding connector 101 (e.g., a gold finger or other type of connector), the corresponding connector 101 passes through the setting space 129 to butt a connector 201. Thus, the lifting and pulling part 121 of the present disclosure may cooperate with the setting space 129 to further meet the needs of practical application.

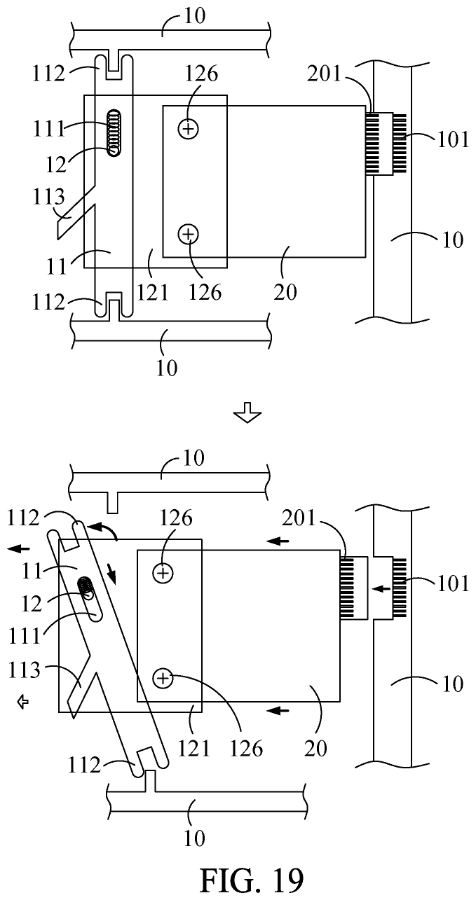

Referring to FIG. 19, as shown in the drawing, in addition to the above embodiments, in one embodiment of the present disclosure, the abutting part 12 is provided at the other object 20 having the connector 201, the connector 201 is pluggable with the corresponding connector 101 of the object 10 (or the connector 201 is hot-pluggable with the corresponding connector 101 of the object 10), wherein the abutting part 12 is assembled to the other object 20 by the lifting and pulling part 121.

Based on the above embodiments, the motion part 11 may be moved by applying force to the operating part 113 during actuation, so that the motion part 11 abuts against the abutting part 12 by the elastic element 13, the motion space 111 moves towards the abutting part 12, the fastening part 112 at one end of the motion part 11 is detached from the object 10, the motion part 11 uses the elastic element 13 to elastically abut against the abutting part 12, the fastening part 112 at the other end of the motion part 11 abuts against the object 10, the fastening parts 112 of the motion part 11 are detached from the object 10, the motion part 11 then drives the lifting and pulling part 121, so that the lifting and pulling part 121 is linked to the other object 20, and the connector 201 of the other object 20 is pluggable with the corresponding connector 101 of the object 10. Thus, the motion part 11 can cooperate with the abutting part 12, so that the corresponding connector 101 of the object 10 is plugged with and the connector 201 of the other object 20 (or hot-plugged), so as to quickly combine and separate at least two objects, and achieve the effect of combining and separating repeatedly and quickly.

While the present invention has been described by means of specific embodiments, those skilled in the art should understand the above description is merely embodiments of the invention, and it should not be considered to limit the scope of the invention. It should be noted that all changes and substitutions which come within the meaning and range of equivalency of the embodiments are intended to be embraced in the scope of the invention. Therefore, the scope of the invention is defined by the claims.

What is claimed is:

1. A motion component structure, comprising:
a motion part, comprising a motion space;
an abutting part, provided in the motion space; and
an elastic element, two ends of the elastic element respectively abut against the motion part and the abutting part, and the elastic element makes the motion part elastically move.

2. The motion component structure according to claim 1, wherein the motion part is provided with a fastening part, the fastening part is used to fasten an object.

3. The motion component structure according to claim 1, wherein the abutting part is provided with a lifting and pulling part, the lifting and pulling part is used to lift and pull another object.

4. The motion component structure according to claim 3, wherein the lifting and pulling part is used to assemble or movably assemble to the object, or the lifting and pulling part is assembled or movably assembled to the object by an assembling part.

5. The motion component structure according to claim 1, wherein the abutting part or the assembling part is riveted, fastened, expanded, welded, locked or bolted to an object or a lifting and pulling part.

6. The motion component structure according to claim 1, wherein the elastic element and the abutting part therebetween is provided with a corresponding member for corresponding and abutting.

7. The motion component structure according to claim 1, wherein the motion part elastically abuts against the abutting part, so that a fastening part of the motion part is detached from an object, and actuates at a lifting and pulling part, or uses the lifting and pulling part to lift and pull another object.

8. The motion component structure according to claim 1, wherein the motion part elastically abuts against the abutting part, so that a fastening part of the motion part is detached from an object.

9. The motion component structure according to claim 1, wherein the motion part elastically abuts against the abutting part, so that a fastening part of the motion part is detached from an object, or a fastening part of the motion part abuts against an object.

10. The motion component structure according to claim 1, wherein a corresponding member between the abutting part, a lifting and pulling part of the abutting part or the elastic element and the abutting part can move in the motion space.

11. The motion component structure according to claim 1, wherein the motion part abuts against the abutting part by the elastic element, so that the motion space moves towards the abutting part.

12. The motion component structure according to claim 1, wherein the abutting part is provided with a positioning part, the positioning part abuts against the elastic element at different angles to act as positioning.

13. The motion component structure according to claim 1, wherein the abutting part has a corresponding member, wherein the corresponding member is combined to the abutting part, or the corresponding member and the abutting part are integrated into one.

14. The motion component structure according to claim 1, wherein the motion part or the abutting part has a guide part, the guide part is used to guide the elastic element.

15. The motion component structure according to claim 1, wherein the motion part is disposed at an object to pull up the object or another object, the object or the other object is a circuit board, chip, connector, heat dissipation body, hard disk, memory, IC, M2 memory, EI.S memory, E3.S memory, metal body or non-metal body.

16. The motion component structure according to claim 15, wherein the other object is provided with a connector, the connector is used to connect with a corresponding connector of the object, or the connector is used to hot-plug with a corresponding connector of the object.

17. The motion component structure according to claim 15, wherein the motion part is provided with a force-saving pushed part, the force-saving pushed part and the object are pushed to move the motion part.

18. The motion component structure according to claim 1, wherein the abutting part is provided with a stopping part, the stopping part is used to stop or limit an object.

19. The motion component structure according to claim 18, wherein the stopping part is provided with an orbital part, and the object moves along a direction of the orbital part.

20. The motion component structure according to claim 1, wherein the abutting part is provided with at least one fixing part, and the object is fixed to the lifting and pulling part by the fixing part.

21. The motion component structure according to claim 1, wherein the abutting part is provided with a lifting and pulling part, the lifting and pulling part is used to lift or assemble a circuit board, memory, IC, M2 memory, EI.S memory, E3.S memory, heat dissipation body, chassis, cabinet, metal body, or non-metal body.

22. The motion component structure according to claim 1, wherein the abutting part is provided with a lifting and pulling part, or the lifting and pulling part is provided with at least one setting space.

23. The motion component structure according to claim 22, wherein the object is provided with a corresponding connector, the corresponding connector passes through the setting space to butt a connector.

24. The motion component structure according to claim 1, wherein the abutting part is provided at another object having the connector, the connector is pluggable with the corresponding connector of an object, or the connector is hot-pluggable with the corresponding connector of an object.

25. The motion component structure according to claim 1, wherein the abutting part is provided with a lifting and pulling part, the lifting and pulling part assembles to another object having the connector, the connector is pluggable with the corresponding connector of an object, or the connector is hot-pluggable with the corresponding connector of an object.
